(19) United States
(12) Patent Application Publication
(10) Pub. No.: US 2013/0015307 A1
(43) Pub. Date: Jan. 17, 2013

(54) BRACKET FOR HARD DISK DRIVE

(71) Applicant: YU-CHEN TING, Tu-Cheng (TW)

(72) Inventor: YU-CHEN TING, Tu-Cheng (TW)

(73) Assignee: HON HAI PRECISION INDUSTRY CO., LTD., Tu-Cheng (TW)

(21) Appl. No.: 13/403,998

(22) Filed: Feb. 24, 2012

(30) Foreign Application Priority Data
Jul. 15, 2011 (TW) 100125036

(51) Int. Cl. H05K 7/00

(52) U.S. Cl. 248/309.1

(57) ABSTRACT

A bracket includes a base panel, a pair of side panels extending from opposite sides of the base panel, and a top panel. The top panel includes a first plate extending substantially perpendicularly from an upper edge of a first side panel of the pair of side panels and a second plate extending substantially perpendicularly from an upper edge of a second side panel of the pair of side panels. The first plate partially overlaps the second plate and is fixed to each other. A first gap is defined in the first plate. A second gap is defined in the second plate. The first gap and the second gap cooperatively form an opening.

### BACKGROUND

1. Technical Field

The present disclosure relates to brackets, and more particularly to a bracket for hard disk drives.

2. Description of Related Art

People rely on computers in their everyday life and business. Thus, a great deal of data storage space such as hard disk drives is needed. Generally, the hard disk drives are accommodated in a bracket mounted in a computer. The bracket includes a base plate, a pair of side plates extending perpendicularly from opposite sides of the base plate, a pair of top flanges extending perpendicularly from top edges of the pair of side plates, and a top plate secured to the pair of top flanges by screws. The hard disk drives vibrate during operation, which also vibrates the bracket. Thus, the top plate can easily deform due to the vibration.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of one embodiment of a bracket for hard disk drives.

FIG. 2 is a schematic cross-sectional view of the bracket of FIG. 1.

FIG. 3 is similar to FIG. 1, but viewed from another aspect.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean at least one.

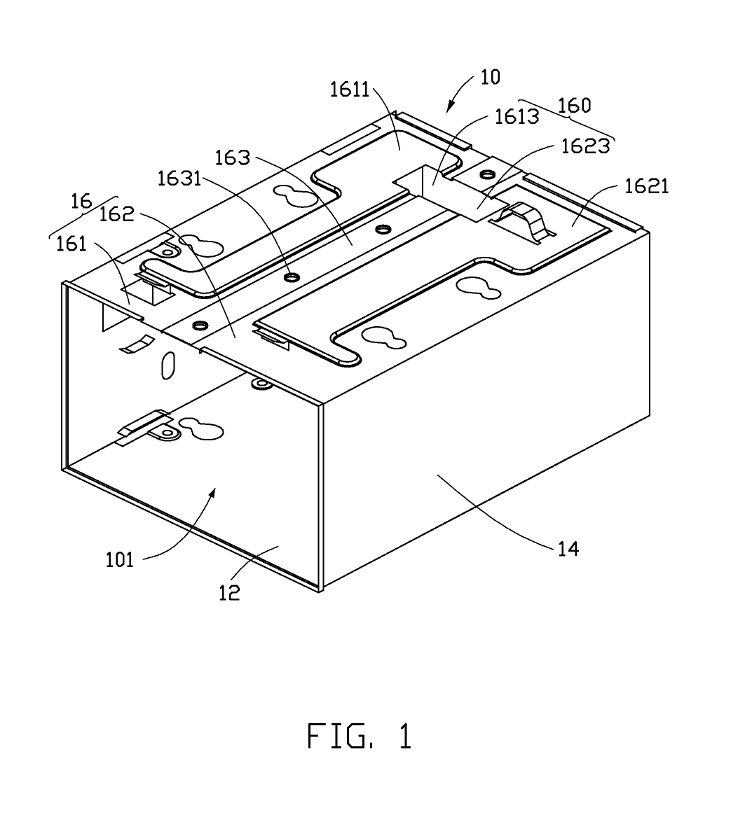

Referring to FIGS. 1 to 3, an embodiment of a bracket 10 includes a base panel 12, a pair of side panels 14 extending substantially perpendicularly from opposite sides of the base panel 12, and a top panel 16 located between the pair of side panels 14.

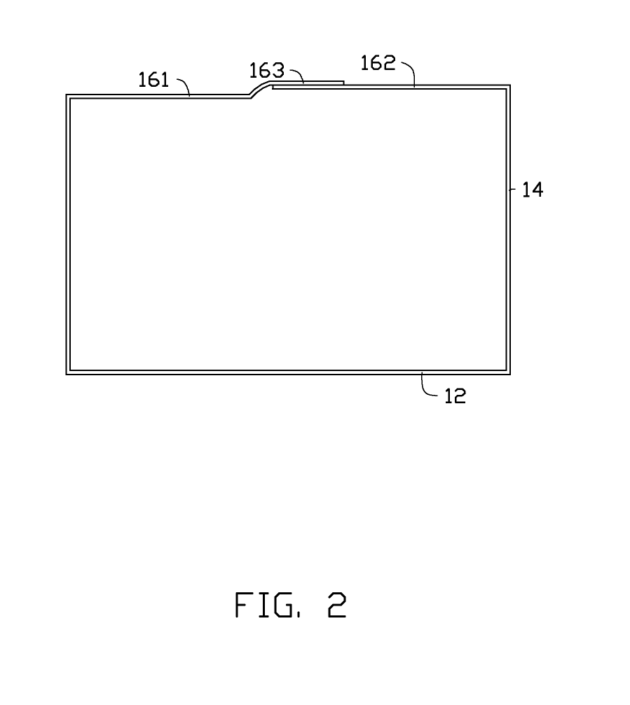

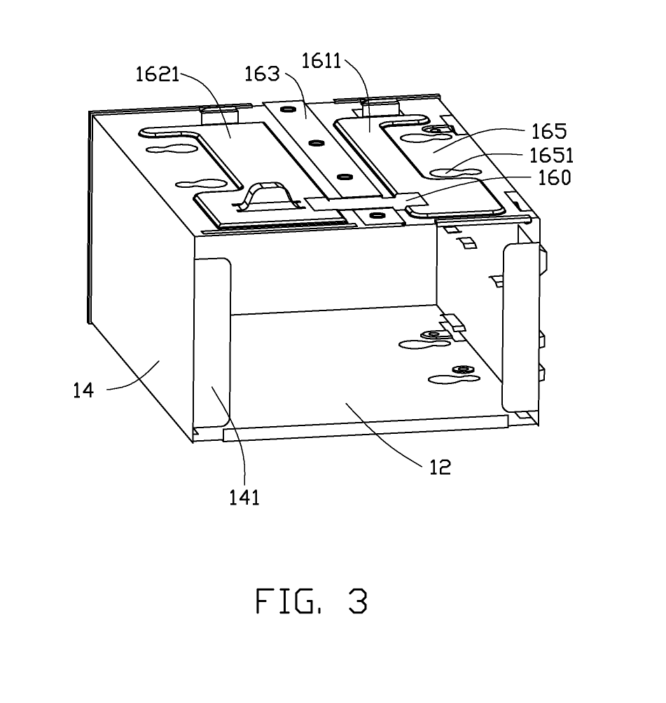

The top panel 16 includes a first plate 161 and a second plate 162 extending substantially perpendicularly from top edges of the pair of side panels 14. The first plate 161 includes a bent flange 163 abutting on the second plate 162. A plurality of securing holes 1631 is defined in the bent flange 163. A plurality of securing posts (not labeled) protrudes from the second plate 162 and engages with the plurality of securing holes 1631. In one embodiment, the bracket 10 is integrally formed by bending a piece of sheet metal (see FIG. 2). A first protruding portion 1611 protrudes upwardly from the first plate 161. A second protruding portion 1621 protrudes upwardly from the second plate 162. A protruding height of the first protruding portion 1611 is substantially equal to that of the second protruding portion 1621. A shape of the first protruding portion 1611 is substantially similar to that of the second protruding portion 1621. The plurality of securing holes 1631 is located between the first protruding portion 1611 and the second protruding portion 1621, and lies on a line that is substantially parallel to the pair of side panels 14. A U-shaped gap portion 165 is defined in each of the first protruding portion 1611 and the second protruding portion 1621. A pair of calabash-shaped holes 1651 is defined in the U-shaped gap portion 165 (see FIG. 3).

A first gap 1613 is defined in the first plate 161. A second gap 1623 is defined in the second plate 162. The first gap 1613 extends from the first protruding portion 1611 to an edge of the bent flange 163. The second gap 1623 extends from the second protruding portion 1621 to an edge of the second plate 162. The first gap 1613 and the second gap 1623 partially overlap with each other to form a substantially rectangular opening 160. A long edge of the opening 160 is substantially perpendicular to the pair of side panels 14. A short edge of the opening 160 is substantially parallel to the pair of side panels 14.

In one embodiment, the bracket 10 has an entrance 101 located at a front side of the bracket 10 (see FIG. 1). A hard disk drive (not shown) can slide into the bracket 10 via the entrance 101. A pair of resisting flanges 141 extends substantially perpendicularly from rear edges of the pair of side panels 14. The pair of resisting flanges 141 prevents the hard disk drive from moving out from a rear side of the bracket 10. The opening 160 is adjacent to the rear side of the bracket 10. A rear portion of the hard disk drive generates greater vibration than any other portion of the hard disk drive during operation. The opening 160 eliminates a vibration path to the top panel 16, which can decrease the vibration of the top panel 16 and decrease vibration noise.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A bracket comprising:
a base panel;
a pair of side panels extending from opposite sides of the base panel, and
a top panel comprising a first plate extending substantially perpendicularly from an upper edge of a first side panel of the pair of side panels and a second plate extending substantially perpendicularly from an upper edge of a second side panel of the pair of side panels;
wherein the first plate partially overlaps the second plate and is fixed to each other, a first gap is defined in the first plate, a second gap is defined in the second plate, and the first gap and the second gap cooperatively form an opening.

2. The bracket of claim 1, wherein the base panel, the pair of side panels, and the top panel cooperatively define an entrance at a front side of the bracket, the opening is located adjacent to a rear side of the bracket, and the front side of the bracket is opposite the rear side of the bracket.

3. The bracket of claim 1, wherein the opening is substantially rectangular shaped, and a long edge of the opening is substantially perpendicular to the pair of side panels.

4. The bracket of claim 1, wherein the first gap and the second gap partially overlap with each other to form the opening.

5. The bracket of claim 4, wherein the first plate comprises a first protruding portion, the second plate comprises a second protruding portion, the first gap is partially defined in the first protruding portion, and the second gap is partially defined in the second protruding portion.

6. The bracket of claim 5, wherein the first plate further comprises a bent flange abutting on the second plate, the first gap extends from the first protruding portion to a first edge of the bent flange, the second gap extends from the second protruding portion to a second edge of the second plate, the first edge abuts an upper side of the second plate, and the second edge abuts a lower side of the first plate.

7. The bracket of claim 6, wherein a plurality of securing holes is defined in the bent flange located between the first protruding portion and the second protruding portion and lies on a line that is substantially parallel to the pair of side panels, the second plate further comprises a plurality of posts engaging with the securing holes for securing the first plate to the second plate.

8. The bracket of claim 5, wherein a U-shaped gap portion is defined in each of the first protruding portion and the second protruding portion.

9. The bracket of claim 8, wherein a pair of calabash-shaped holes is defined in the U-shaped gap portions of the first plate and the second plate.

10. A bracket comprising:
a base panel;
a pair of side panels extending from opposite sides of the base panel, and
a top panel comprising a first plate extending substantially perpendicularly from an upper edge of a first side panel of the pair of side panels along a first direction and a second plate extending substantially perpendicularly from an upper edge of a second side panel of the pair of side panels a long a second direction that is opposite to the first direction, a first gap being defined in the first plate, a second gap being defined in the second plate;
wherein the first plate comprises a bent flange abutting on the second plate and secured to the second plate, and the first gap and second gap partially overlap with each other and cooperatively form an opening.

11. The bracket of claim 10, wherein the base panel, the pair of side panels, and the top panel cooperatively define an entrance at a front side of the bracket, the opening is located adjacent to a rear side of the bracket, and the front side of the bracket is opposite the rear side of the bracket.

12. The bracket of claim 10, wherein the opening is substantially rectangular shaped, and a long edge of the opening is substantially perpendicular to the pair of side panels.

13. The bracket of claim 10, wherein the first plate further comprises a first protruding portion, the second plate comprises a second protruding portion, the first gap is partially defined in the first protruding portion, and the second gap is partially defined in the second protruding portion.

14. The bracket of claim 13, wherein the first gap extends from the first protruding portion to a first edge of the bent flange, the second gap extends from the second protruding portion to a second edge of the second plate, the first edge abuts an upper side of the second plate, and the second edge abuts a lower side of the first plate.

15. The bracket of claim 14, wherein a plurality of securing holes is defined in the bent flange and lies on a line that is substantially parallel to the pair of side panels, the second plate further comprises a plurality of posts engaging with the securing holes for securing the first plate to the second plate.

16. The bracket of claim 13, wherein a U-shaped gap portion is defined in each of the first protruding portion and the second protruding portion.

17. The bracket of claim 16, wherein a pair of calabash-shaped holes is defined in the U-shaped gap portion of each of the first plate and the second plate.
